(19) United States
(12) Patent Application Publication
(10) Pub. No.: US 2016/0080659 A1
(43) Pub. Date: Mar. 17, 2016

(54) Assistance System of a Motor Vehicle, with a Camera Comprising an Image Sensor, as well as Image Sensor of a Camera

(71) Applicant: Conti Temic microelectronic GmbH, Nuernberg (DE)

(72) Inventors: Dieter KROEKEL, Eriskirch (DE); Andrej RITTER, Langenargen (DE)

(21) Appl. No.: 14/850,205

(22) Filed: Sep. 10, 2015

(30) Foreign Application Priority Data
Sep. 15, 2014 (DE) 10 2014 218 459.2

(51) Int. Cl. H04N 5/247; H04N 9/04; H01L 27/146

(52) U.S. Cl. CPC H04N 5/247; H01L 27/14645; H01L 27/14621; H04N 9/045; H04N 2209/042

(57) ABSTRACT

An assistance system of a motor vehicle has a camera including an image sensor. The image sensor includes first sensor elements that are sensitive to electromagnetic radiation in a specific region in the visible spectral range, and second sensor elements that are sensitive to electromagnetic radiation in the entire visible spectral range. The sensor elements are arranged in a grid-shaped configuration in a first region, a second region and a third region of the image sensor. The density of the second sensor elements is greater in the third region than in the second region, and is greater in the second region than in the first region.

### PRIORITY CLAIM

This application is based on and claims the priority under 35 USC 119 of German Patent Application 10 2014 218 459.2 filed on Sep. 15, 2014, the entire disclosure of which is incorporated herein by reference.

### FIELD OF THE INVENTION

The invention relates an assistance system of a motor vehicle, with a camera comprising an image sensor, as well as an image sensor of a camera.

### BACKGROUND INFORMATION

Motor vehicles include a plurality of assistance systems, such as e.g. rain sensors, lane-keeping assistants or fatigue alert assistants. Each assistance system of this type comprises a camera, by means of which the front pane (e.g. the windshield), the lane on the roadway, or the driver is detected during operation. The detected image is checked for deviations from a specific target state, and if any deviation exists, then an actor or actuator is activated, such as a wiper motor, a motor for influencing the steering angle, or an acoustic or optical signal transmitter.

Detection of the images is usually performed by means of an image sensor, which has a matrix- or grid-shaped arrangement of sensor elements. The sensor elements themselves work with CCD- or CMOS-technology. By means of such technology merely a brightness value can be detected. To receive color information, each sensor element comprises a color filter, which is transparent merely for light of a specific wavelength range. As a result, the sensitivity and thus the actual resolution is reduced. Furthermore, an interpolation of the brightness values between sensor elements is necessary, which comprise an equivalent color filter, i.e. a filter, which allows the passage of light of the same wavelength.

The sensor elements comprising the color filters are positioned in a specific arrangement, in order to obtain on the one hand a comparably high resolution and on the other hand a comparably high color information quality. Here, the color filters are always arranged in the same pattern, for example in a so-called Bayer pattern. An alternative is to use so-called clear pixels, i.e. sensor elements that have no color filter. These are arranged for example in isolated manner, thus directly adjacent to sensor elements with color filters, or in columns, e.g. in a so-called RGBW pattern.

### SUMMARY OF THE INVENTION

An object of one or more embodiments of the invention is to provide both a particularly suitable assistance system with a camera and a particularly suitable image sensor of a camera, which has suitably an increased information quality.

The above object is achieved according to an embodiment of the invention in an assistance system having features as set forth herein, and according to another embodiment of the invention in an image sensor having features as set forth herein.

The assistance system is a component of a motor vehicle and comprises a camera. For example by means of the assistance system a traffic flow in front of the motor vehicle is monitored. As an alternative or in combination thereto by means of the assistance system a positioning of the motor vehicle on a road, in particular on a lane, is determined and/or possible traffic signs are detected. The camera comprises an image sensor, which includes a plurality of first and second sensor elements, which are arranged grid-shaped to form columns and lines. In other words, a matrix arrangement is created by means of the first and second sensor elements. In particular, the image sensor comprises a total number of 256, 512, 1024 or an integer multiple thereof of columns and/or lines. The image sensor works for example with the CCD technology or particularly preferred with the CMOS technology.

The first sensor elements are sensitive for electromagnetic radiation in a specific region in the visible spectral range. In other words, during operation by means of the first sensor elements merely a fraction of electromagnetic radiation is detected, which has a wavelength between 350 nm and 790 nm. Here, specific wavelength ranges are detected not at all or only comparably weakly. For example, the sensitivity in the specific region is increased by more than 10 times compared to the remaining regions. The wavelengths of the electromagnetic radiation in the specific region differ usefully by less than 100 nm, 80 nm, 50 nm or 20 nm.

The second sensor elements for the electromagnetic radiation on the other hand are sensitive in the entire region of the visible spectral range, the sensitivity for example being constant or corresponding to the respective physical specifications of the material of the image sensor itself, i.e. in particular being dependent on the band structure of the used semiconductor material. Suitably, all first sensor elements and all second sensor elements are identical in construction. Preferably, the first sensor elements correspond to the second sensor elements plus a color filter. In other words, the first sensor elements are designed each by means of a color filter, by means of which the sensitivity with the exception of the respective specific region is reduced. For example, also the second sensor elements comprise a filter, by means of which, however, merely components of electromagnetic radiation are filtered, which have wavelengths less than e.g. 390 nm and/or exceeding 790 nm. Alternatively, the second sensor elements have no filters.

The image sensor comprises further a first region, a second region and a third region and is in particular divided into these regions. The regions are formed by means of the sensor elements and consist preferably of these sensor elements. Here, at least one, usefully a number, of the columns or lines runs through two of the regions and for example through all three regions. In other words, the first, second and third region is formed at least by means of sections of the columns or lines. In again other words, the matrix arrangement of the individual sensor elements is divided into the first, second and third region. Here, the density of the second sensor elements is greater in the third region than in the second region. In other words, the average number of second sensor elements per area and/or per sensor elements is greater in the third region than in the second region. Hence, the third region comprises more second sensor elements than the second region, in case the two regions are identical in size. Furthermore, the density of the second sensor elements is greater in the second region than in the first region. Suitably, the three regions are formed merely by means of the first and second sensor elements. In particular the density of the first sensor elements is greater in the first region than in the second region and/or is greater in the second region than in the third region. Suitably, here the first and second sensor elements are arranged in a specific repeating pattern. For example, the distance between adjacent second sensor elements is greater in the first region than in the second and there it is greater than in the third region. Suitably, the patterns differ between the individual regions. Preferably, the pattern is constant in the respective region. Preferably, the number of sensor elements per region is 16, 32, 128 or more. It is useful that the sensor elements are arranged per region in a matrix, which is greater than or equal to a 4×4, 10×10, 20×20 or 50×50 matrix. Preferably, the number of columns and/or lines per region is greater than or equal to 2, 10, 20, 30, 50, or 100.

In this way it is possible to detect comparably much color information by means of the first region. On the other hand, by means of the third region a comparably high sensitivity and thus actual resolution is realized, by means of which also comparably remote objects can be detected. By means of the second region it is possible to detect objects with a greater distance to the motor vehicle than it is possible with a detection by means of the first region. Here, however, compared to the detection merely by means of the third region the determination of a possible color of the object is possible. Hence, it is possible to optimize the image sensor both to a comparably high color information quality and a comparatively high sensitivity. Based on the second region, in addition the detection of objects is possible, which could neither be detected by the first nor by the third region. At least, however, a comparably fluid transition between the first and the third region is guaranteed. If, besides, the object is detected by means of different regions, i.e. one part of the object by means of the first region and another part of the object by means of the second region, the object can still be reconstructed as a whole (either in color or in grey shades). Thus the information quality of the assistance system is increased.

Usefully, the second region is arranged between the first region and the third region so that a gradual transition of the density of the second sensor elements from the third region to the first region is given. For example, the first region borders on the second region. In other words, the second region is in direct contact with the first region. As an alternative or in combination thereto the second region borders on the third region. In this way, by means of the image sensor first a comparably remote object is detected by means of the third region. When the motor vehicle approaches this object, it is possible to detect this object by means of the second region and in addition to the presence and the position of the object to also determine at least partially its color. If the distance between the object and the motor vehicle is comparably small, it is possible to detect the object by means of the first region, and to obtain in this way comparably much color information on the object.

In an especially preferred manner, the third region is a central region of the image sensor. When the camera is oriented towards a region in front of the motor vehicle, i.e. in its moving direction, thus by means of the third region the detection of comparably remote objects is possible, which are in front of the motor vehicle. Usefully, the first region is an edge region of the image sensor. If the camera is oriented towards the moving direction of the motor vehicle, it is thus possible to detect by means of the image sensor colored traffic signs, which are located on the side of the motor vehicle and thus are significant for the driver of the vehicle.

For example, the first region is substantially arranged in a U-shape, wherein on the horizontal leg usefully an upper region of the image to be detected is shown by means of a lens of the camera. In other words, by means of this leg a sky, a possible tunnel ceiling or the like is detected. Hence, it is possible to detect by means of the first region also traffic signs, which are arranged on a traffic sign bridge above a road on which the vehicle is located, a tunnel ceiling or the like. Whereas by means of the two vertical legs of the first region traffic signs are detected, which are positioned on the side of a lane of the motor vehicle.

For example, the second region is arranged in a U-shape, the third region being also designed in a U-shape and enclosing at least partially the second region on the outside. In this way, a traffic sign is detected when the motor vehicle approaches it first by means of the second region and only with a reduced distance to the traffic sign it is detected by means of the first region. Hence, first by means of the second region the presence of an at least partially colored traffic sign is determined. If the color information, which is identified in the detection, is sufficient to detect the meaning of the traffic sign, the meaning is reconfirmed when detecting the traffic sign by means of the first region. For example, already during detection by means of the second region it can be differentiated whether the traffic sign is a prohibition or an abolishment of the prohibition. If the identification of the traffic sign meaning is not possible during detection by means of the second region, the meaning is identified as soon as more color information is available, namely when the traffic sign is determined by means of the first region. Here, due to the detection by means of the second region it is already known at which position the traffic sign is to be expected when entering the first region.

Suitably, the third region is substantially rectangular and is arranged in particular in a middle region of the image sensor. In particular, the third region is distanced from the two vertical edges of the image sensor. In this way it is possible to detect by means of the third region also comparably remote objects, in case an appropriate objective of the camera is used.

Usefully, the density of the first sensor elements in the third region is lower than the density of the second sensor elements in the third region. In other words, the third region comprises less first sensor elements than second sensor elements. For example, the third region is free of first sensor elements. In other words, the third region is formed merely by means of the second sensor elements. Hence, when detecting an object by means of the third region it is not possible to extract color information. On the other hand, when detecting an object by means of the third region the resolution is comparably high due to the measured values of the second sensor elements, which correspond to absolute brightness values.

As an alternative or in combination thereto the density of the first sensor elements is greater in the first region than the density of the second sensor elements in the first region. Hence, the first region comprises more first sensor elements than second sensor elements. In an especially preferred manner the first region is free of second sensor elements and is preferably formed merely by means of first sensor elements. In this way, a determination of a color of an object detected by means of the first region is facilitated. For example, the first sensor elements of the first region are arranged in a Bayer pattern. If the first region comprises second sensor elements, the sensor elements are arranged for example in a French, Italian, Kodak or RGBW pattern. In this way, both a determination of the color and a comparably high sensitivity are given. As an alternative or in combination thereto the sensor elements of the second region are arranged for example in a French, Italian, Kodak or RGBW pattern.

For example, the image sensor comprises a fourth region, which is also formed by means of the sensor elements. Here, the density of the second sensor elements in the fourth region is greater than in the second region. Further, the density of the second sensor elements in the fourth region is lower than in the third region. In this way, a further gradation of the sensitivity of the image sensor and its possibility for color information extraction is given. Usefully, the fourth region is arranged between the second and the third region. In this way, the gradual transition of the density between the first and the third region is refined. Hence, it is possible to optimize the fourth region towards an increased sensitivity and the second region towards an increased extraction of color information.

In a particularly preferred embodiment of the invention the camera comprises an evaluation device, by means of which the measured data detected by means of the first and second sensor elements are evaluated during operation of the assistance system and a reproduction is produced. Here, usefully a pixel of the reproduction is assigned to each of the measured values detected by means of the first and second sensor elements, wherein the position of the pixel corresponds to the position of the respective sensor element. Here, the respective measured value detected by means of the second sensor elements corresponds to a brightness value of the reproduction comprising the pixel, whereas each of the measured value detected by means of the first sensor elements corresponds to a color value, which corresponds to the respective sensitive region of the respective first sensor element.

Preferably, a color value is assigned at least to the pixels corresponding to the second sensor elements of the second region and/or for example the second sensor elements of the first and or third region, which color value is produced by means of interpolation of the measured values of the respective first sensor elements. In other words, a color value is assigned to each second sensor element, wherein this color value corresponds for example to the average value of the measured values, which was detected by means of adjacent first sensor elements comprising the same color filter. In an especially preferred manner, however, a binomial filter is used for this purpose, i.e. the adjacent measured values of the respective first sensor elements accordingly weighted.

Usefully, the first sensor elements comprise at least two different color filters. In other words, two of the first sensor elements differ by their respective color filter. Hence, these first sensor elements are sensitive in different regions in the visible spectral range. Usefully, by means of the first sensor elements a first amount and a second amount are formed, wherein all first sensor elements of the same amount are sensitive in the same specific region in the visible spectral range. Here, the specific region differs between the first amount and the second amount. For example, the two specific regions differ by a wavelength of more than 100 nm. In this way, an analysis of the reproduction as to the presence of elements available not only in one single color is possible.

For example, the first sensor elements comprise three or more different color filters. In other words, at least a third amount is formed by means of the first sensor elements, whose color filter differs from the color filter of the first and second amount. In this way, the number and quality of color information of the reproduction are increased.

Suitably, a color filter for the spectral colors red, green or blue is used as color filter. Here, it is useful that by means of the blue color filter electromagnetic radiation with a wavelength between 450 nm to 500 nm is substantially not absorbed, that by means of the green color filter electromagnetic radiation with a wavelength of 520 nm to 565 nm is not absorbed and that by means of the red color filter electromagnetic radiation with a wavelength between 625 nm to 650 nm, to 690 nm or to 740 nm is not absorbed, whereas the complementary regions each are absorbed by means of the respective filter. In other words, the color filters are transparent merely for electromagnetic radiation with a wavelength between 450 nm and 500 nm, 520 nm and 565 nm or 625 nm to 650 nm, to 690 nm or to 740 nm. Preferably, tolerances of substantially 5 nm apply with the respective wavelengths.

Usefully, the number of the first sensor elements with the green color filter is preferably equal to twice the first sensor elements with the red color filter and/or the number of the first sensor elements with the blue color filter. Suitably, the number of the first sensor elements with the red color filter is equal to the number of the sensor elements with the blue color filter.

Usefully, the first sensor elements in the first region are arranged in a Bayer pattern, in case the first region comprises second elements, the sensor elements in the first region are preferably arranged in a French, RGBW or Kodak pattern. As an alternative or in combination thereto the sensor elements in the second region and/or third region are arranged in a French, RGBW or Kodak pattern. Preferably, the pattern of the second or third region is equal to the pattern of the first region, wherein between adjacent first sensor elements at least one of the second sensor elements is arranged.

In an alternative embodiment the first sensor elements comprise at least two different color filters, each of them working either for the spectral color yellow, the spectral color magenta or the spectral color cyan. Usefully, the image sensor comprises first sensor elements with color filters for the colors yellow, magenta and cyan, so that a comparably comprehensive reconstruction of color information is possible, albeit by means of calculating rules other than with color filters for the spectral colors red, green and blue. In other words, the image sensor comprises three different types of first sensor elements, which differ by the respective color filter.

The image sensor is a component of a camera and comprises a number of columns and lines, which are suitably adjacent to each other. Each column and line is formed by means of a plurality of sensor elements, which are consequently arranged in a matrix. Here, the sensor elements are divided into first and second sensor elements. In other words, the image sensor comprises the first and second sensor elements and consists preferably of these elements or comprises otherwise in particular at least only control connections and/or an electronic control unit. The first sensor elements are sensitive merely for a specific region in the visible spectral range of the electromagnetic radiation, whereas the second sensor elements are sensitive for electromagnetic radiation in the entire region of the visible spectral range. In other words, the second sensor elements are sensitive along a greater region of the electromagnetic radiation in the visible range than the respective first sensor elements.

The first and second sensor elements are arranged in a first region, a second region and a third region, wherein the respective regions are formed preferably by means of the sensor elements. The density of the second sensor elements is greater in the third region than in the second region. In other words, on average in the third region more second sensor elements per area or per absolute number of sensor elements are available than in the second region. Further, the density of the second sensor elements is greater in the second region than in the first region. Preferably, at least a number of the columns and/or lines runs through two of the regions or through the first region as well as through the second region as well as through the third region.

### BRIEF DESCRIPTION OF THE DRAWINGS

In the following, exemplary embodiments of the invention will be apparent from the accompanying drawings, in which

FIG. 1 shows an assistance system with a camera, in a schematically simplified manner,

FIG. 2 shows a first embodiment of an image sensor of the camera, in a plan view,

FIG. 3 shows a second embodiment of the image sensor according to FIG. 2, and

FIG. 4-7 each shows a color pattern of the image sensors.

In all drawings, like reference numbers represent like parts.

### DETAILED DESCRIPTION OF EXAMPLE EMBODIMENTS OF THE INVENTION

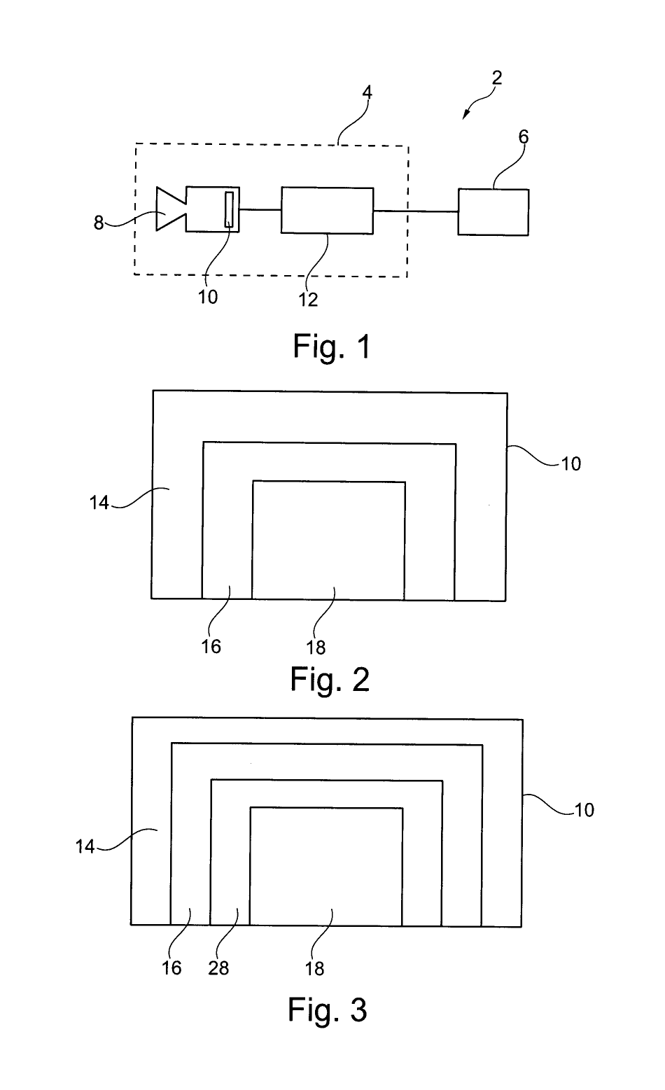

In FIG. 1 an assistance system 2 of a motor vehicle is shown schematically simplified. The assistance system 2 comprises a camera 4 and a signal device 6, which are coupled to each other fail-safe. By means of the signal device 6 the driver of the motor vehicle is informed on the presence of a traffic sign, which was detected with the aid of the reproductions produced by means of the camera 4. The signal device 6 is a head-up display, by means of which this information is projected onto the front pane of the motor vehicle. As an alternative, the signal device 6 is adapted to acoustically or haptically inform the driver or to transmit the information by means of electrical signals to further systems of the motor vehicle, such as e.g. a system for controlling the brakes, the acceleration or the steering.

The camera 4 comprises an objective 8 with a plastic or glass lens or a combination thereof, by means of which an image sensor 10 is covered. The brightness values, which are detected by means of the image sensor 10 based on CMOS technology are supplied to an evaluation device 12, by means of which a reproduction is reconstructed from the brightness values detected by means of the image sensor 10, i.e. from the recorded measured data. From this reproduction, different objects such as further motor vehicles, pedestrians, street signs are detected by means of an image processing algorithm.

In FIG. 2 the image sensor 10 is shown in a plan view. Here, the image sensor 10 is oriented according to the image to be produced by means of the camera 4. In other words, an upper region of the image sensor 10 corresponds to an upper region of the image to be produced. For example, the image sensor 10 is constructed twisted by 180°, in case the objective 8 works merely in a converging lens type. The image sensor 10 comprises a first region 14, a second region 16 and a third region 18. The first region 14 here forms the two vertical edge regions as well as the upper horizontal edge region of the image sensor 10 and is thus designed in a U-shape. On the first region 14 the second region 16 borders directly, which is also designed in a U-shape. The third region 18 bordering on the second region is rectangular, wherein the horizontal and vertical extension of the third region 18 is greater than twice the respective extension of the image sensor 10. Here, the third region 18 forms at least partially the lower edge of the rectangular image sensor 10.

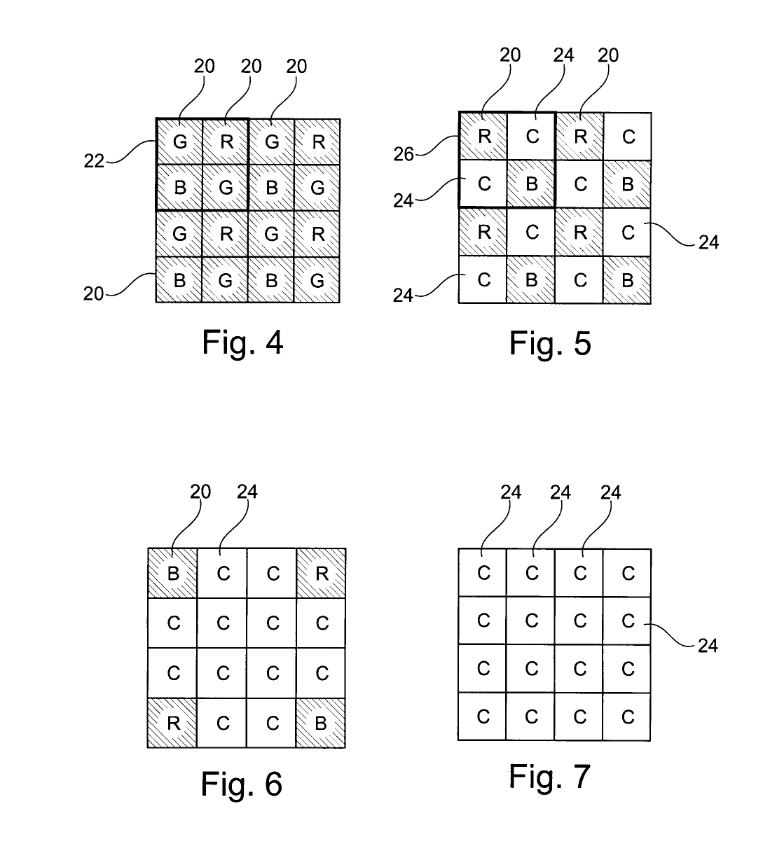

The first region 14 is formed exclusively by means of first sensor elements 20, which comprise either a red color filter R, a green color filter G or a blue color filter B, which is transparent merely for electromagnetic radiation with a wavelength corresponding to the spectral color red, green or blue. The first sensor elements 20 are arranged grid-like to form lines and columns, as is schematically shown in FIG. 4. In other words, a matrix arrangement is created by means of the sensor elements 20. The first sensor elements 20 are arranged according to a repeating Bayer pattern 22. Each Bayer pattern 22 consists of two first sensor elements 20 with a green color filter G, which are diagonally offset, and of one of the first sensor elements 20 with a red color filter R and of one of the first sensor elements 20 with a blue color filter B. As an alternative, the first line of the pattern is formed of one of the first sensor elements 20 with a red color filter R, and of one of the first sensor elements 20 with a green color filter G and the second line is formed of one of the first sensor elements 20 with a green color filter G and of one of the first sensor elements 20 with a blue color filter B, wherein the first sensor elements 20 with a green color filter G are also diagonally offset, however, twisted by 90° compared to the preceding pattern. In a further alternative, the first sensor element 20 is exchanged with the blue color filter B and the first sensor element 20 with the red color filter R.

To form the second region 16 both the first sensor elements 20 and the second sensor elements 24 are used, which are substantially equal in construction to the first sensor elements 20, which, however, do not comprise a color filter. In other words, the second sensor elements 24 have no color filter. However, the second sensor elements 20 comprise an UV- and IR-cut filter C, which is realized for example by means of the objective 8 and/or an IR-cut filter covering the complete image sensor 10. As a result, the two sensor elements 24 are sensitive for electromagnetic radiation in the entire region of the visible spectral range, at least, however, in a wavelength range of 400 nm to 650 nm-690 nm. The sensor elements 20, 24 are arranged to a repeating French pattern 26, which is shown in FIG. 5. The French pattern 26 is a 2×2 matrix, wherein the first line is formed by means of one of the first sensor elements 20 with the red color filter R as well as one of the second sensor elements 24. The second line is formed by means of another one of the second sensor elements 24 as well as of one of the first sensor elements 20 with the blue color filter B. The two second sensor elements 24 of the French pattern 26 are diagonally offset.

Consequently, the second region 16 comprises two second sensor elements 24 per four sensor elements 20, 24, whereas the first region 14 comprises none of the second sensor elements 24 per four sensor elements 20, 22. Thus, the density at second sensor elements 24 in the second region 16 is increased compared to the first region 14. As a result, the sensitivity and resolution in grey shades of the image sensor 10 in the second region 16 is increased compared to the first region 14, wherein the quality of detected color information is reduced. It is true that by means of the evaluation device 12 also a green channel can be calculated from the measured values recorded by means of the sensor elements 20, 24 of the second region 16. But here a quality loss is given compared with the direct detection by means of the first sensor elements 20 with a green color filter G of the first region 14. The third region 18 is formed only by means of the second sensor elements 24, as is partially shown in FIG. 7. Consequently, no color extraction is possible by means of the measured data of the sensor elements 24 of the third region 18, whereas the sensitivity and susceptibility in this region is increased, i.e. the sensitivity and resolution in grey shades of the image sensor 10 is at maximum. The individual sensor elements 20, 24 of the different regions 14, 16, 18 are arranged to form common columns and lines. In other words, the individual sensor elements 20, 24 are aligned in the respective transition between the regions 14, 16, 18.

In FIG. 3 a further embodiment of the image sensor 10 is shown according to FIG. 2. Here, the third region 18 is left substantially unchanged. In other words, the position of the third region 18 and its formation by means of the second sensor elements 24 corresponds according to FIG. 7 to the preceding embodiment. Then again, the first region 14 as well as the second region 16 is changed. The horizontal and vertical extension of the first region 14 is reduced, i.e. its respective thickness is reduced, wherein the first region 14 still forms at least partially the edge region of the image sensor 10. Thus, the two vertical and the upper horizontal edge are formed by means of the first region 14. Further, the arrangement of the first sensor elements 20 is maintained according to the Bayer pattern arrangement 22 shown in FIG. 4.

The second region 16 is still formed by means of first and second sensor elements 20, 24, which are arranged in the French pattern 26 shown in FIG. 5. Further, the second region 16 borders on the first region 14. The second region 16 is still designed in a U-shape, wherein the thickness of the legs forming the U is reduced. In the remaining free space between the second region 16 and the third region 18 there is a fourth region 28, which is designed in a U-shape, and which borders on the second region 16 and on the third region 18. The fourth region 28 is formed both by means of first sensor elements 20 and by means of second sensor elements 24. Here, three second sensor elements 24 each exist per 2×2 matrix, so that the density of the second sensor elements 24 in the fourth region 28 is greater than in the second region 16, but lower than in the third region 18.

The repeating pattern of the fourth region 28 is formed by means of a 4×4 matrix, wherein the edge regions are formed each by means of one of the first sensor elements 20. Diagonally opposed edges comprise either the red color filter R or the blue color filter B. The other sensor elements are second sensor elements 24. Alternatively, the pattern of the fourth region 28 corresponds to the Bayer pattern 22 or the French pattern 26, wherein between the two existing columns and lines one or more column and line is added, which is formed merely by means of second sensor elements 24. In other words, the pattern is formed of a 4×4 matrix, which comprises twelve or fourteen second sensor elements 24.

In an alternative the image sensor 10 comprises merely the first, second and third region 14, 16, 18, which are arranged according to the embodiment shown in FIG. 2. Here, the first region 14 comprises the Bayer pattern 22, the second region 16 comprises the French pattern 26. The third region 18 is formed by means of repetitions of the pattern shown in FIG. 6.

To reconstruct the reproduction of the measured values produced by means of the sensor elements 20, 24 a color value is assigned by means of the evaluation device 12 to each second sensor element 24 of the second region 16. For this purpose, all sensor elements 20, 24, which lie between adjacent first sensor elements 20 with the red color filter R, an intermediate value between these two measured values is assigned by means of a binomial filter. The same method is carried out for the remaining first sensor elements 24 with the blue color filter B or the green color filter G, in case they exist.

The invention is not restricted to the above described exemplary embodiments. Moreover, also other variants of the invention can be derived by the skilled person without leaving the subject-matter of the invention. In particular, furthermore all individual features, which were described with reference to the exemplary embodiments, can be combined with each other also in other way without leaving the subject-matter of the invention.

Although the invention has been described with reference to specific example embodiments, it will be appreciated that it is intended to cover all modifications and equivalents within the scope of the appended claims. It should also be understood that the present disclosure includes all possible combinations of any individual features recited in any of the appended claims. The abstract of the disclosure does not define or limit the claimed invention, but rather merely abstracts certain features disclosed in the application.

### LIST OF REFERENCE NUMERALS

2 assistance system
4 camera
6 signal device
8 objective
10 image sensor
12 evaluation device
14 first region
16 second region
18 third region
20 first sensor element
22 Bayer pattern
24 second sensor element
26 French pattern
28 fourth region
C IR- and UV-cut filter
R red color filter
G green color filter
B blue color filter

We claim:

1. An assistance system of a motor vehicle, with a camera comprising an image sensor, wherein the image sensor includes first sensor elements that are sensitive to electromagnetic radiation in a specific region in a visible spectral range, and second sensor elements that are sensitive to electromagnetic radiation in the entire visible spectral range, wherein the sensor elements are arranged in a grid-shaped configuration in a first region, a second region and a third region of the image sensor, and wherein a density of the second sensor elements is greater in the third region than in the second region and is greater in the second region than in the first region.

2. An assistance system according to claim 1, wherein the second region is arranged between the first region and the third region, and wherein the second region borders on at least one of the first region and the third region.

3. An assistance system according to claim 1, wherein the first region is an edge region adjoining an edge of the image sensor.

4. An assistance system according to claim 3, wherein the first region is U-shaped.

5. An assistance system according to claim 1, wherein the third region is rectangular.

6. An assistance system according to claim 1, wherein the third region contains none of the first sensor elements.

7. An assistance system according to claim 1, wherein the first region contains none of the second sensor elements.

8. An assistance system according to claim 1, wherein the image sensor further comprises a fourth region arranged between the second region and the third region, and wherein a density of the second sensor elements in the fourth region is greater than in the second region and lower than in the third region.

9. An assistance system according to claim 1, wherein the first sensor elements comprise at least two different color filters.

10. An image sensor for a camera, wherein the image sensor includes first sensor elements that are sensitive to electromagnetic radiation in a specific region in a visible spectral range, and second sensor elements that are sensitive to electromagnetic radiation in the entire visible spectral range, wherein the sensor elements are arranged in a grid-shaped configuration in a first region, a second region and a third region of the image sensor, and wherein a density of the second sensor elements is greater in the third region than in the second region and is greater in the second region than in the first region.
